(19) United States
(12) Patent Application Publication
(10) Pub. No.: US 2014/0210019 A1
(43) Pub. Date: Jul. 31, 2014

(54) LOW-COST PACKAGE FOR INTEGRATED MEMS SENSORS

(71) Applicant: INVENSENSE, INC., Sunnyvale, CA (US)

(72) Inventors: Steven S. NASIRI, Saratoga, CA (US); Nim H. TEA, Cupertino, CA (US); Stephen LLOYD, Los Altos, CA (US)

(73) Assignee: INVENSENSE, INC., Sunnyvale, CA (US)

(21) Appl. No.: 13/753,753

(22) Filed: Jan. 30, 2013

(51) Int. Cl. B81B 3/00; B81C 1/00

(52) U.S. Cl. CPC B81B 3/0018; B81C 1/00134
USPC 257/415; 438/51

(57) ABSTRACT

An integrated MEMS sensor package is disclosed. The package comprises a sensor chip with a top surface and a bottom surface. The top surface comprises an opening. The bottom surface is attached to a substrate with electrical inter-connects. A lid is coupled to the top surface with an adhesive material. The lid may have an opening to expose the sensor chip to ambient environment.

### FIELD OF THE INVENTION

The present invention relates generally to MEMS packages and more specifically to packages for integrated MEM sensors.

### BACKGROUND

There is a need to provide low cost packages for MEM sensors that need access to the ambient environment. Examples of such sensors are pressure sensors, chemical sensors, sound sensors and the like. As the devices become smaller in size the packages for the sensors must become correspondingly smaller. What is needed is a package for MEM sensors that address the above-identified issue.

The package should be simple, easily implemented, cost effective and adaptable to existing environments. The present invention addresses such a need.

### SUMMARY OF THE INVENTION

An integrated MEMS sensor package is disclosed. The package comprises a sensor chip with a top surface and a bottom surface. In some embodiments, the top surface comprises an opening. The bottom surface is attached to a substrate with electrical inter-connects. A lid cover with an opening is attached to the top surface; the opening allows for a path for the ambient environment to the MEMS.

Other aspects and advantages of the present invention will become apparent from the following detailed description, taken in conjunction with the accompanying drawings which illustrate, by way of example, the principles of the invention.

### BRIEF DESCRIPTION OF THE DRAWINGS

FIGS. 1A, 1B, and 1C illustrate a first embodiment of a package integrated MEMS sensors in accordance with the present invention.

FIGS. 2A and 2B illustrate a second embodiment of a package integrated MEMS sensors in accordance with the present invention.

FIG. 3 illustrates a top view of the MEMS package with the cover lid removed.

FIGS. 4A and 4B illustrate a third embodiment of an MEMS package in accordance with an embodiment.

FIGS. 5A and 5B illustrate a fourth embodiment of an MEMS package 500 in accordance with an embodiment.

FIGS. 6A and 6B illustrate a fifth embodiment of an MEMS package 600 in accordance with an embodiment.

FIG. 7 illustrates an embodiment of testing MEMS packages.

### DETAILED DESCRIPTION OF PREFERRED EMBODIMENTS

The present invention relates generally to MEMS and more specifically to integrated MEMS sensors. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

An integrated MEMS sensor package is disclosed that has significant advantages over conventional sensor packages. An integrated MEMS sensor package in accordance with an embodiment enables a reduction in all three package dimensions, thereby lowering cost. For example, the package size is 4 mm×4 mm×1.0 mm using existing multi-layer substrate with a metal lid. By providing a package in accordance with the present invention, the same die can fit in a 3 mm×3 mm×0.8 mm.

Utilizing a package in accordance with the present invention may also reduce product development time to a high volume market with rapid package prototype. An alternative to achieve a smaller package size is to use film assisted molding which has long lead time for prototype because a custom mold is required. A package in accordance with the described embodiments may also provide stress isolation between a MEMS die and a substrate by an attachment mechanism. To describe the features of the package in more detail, refer now to the following description in conjunction with the accompanying figures.

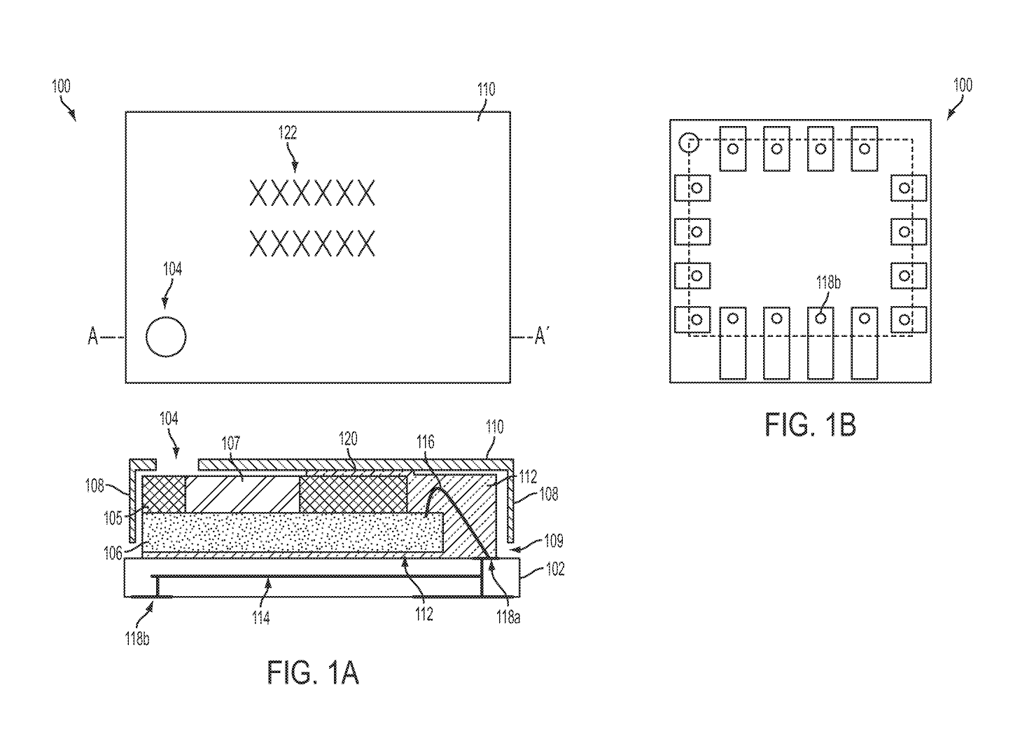

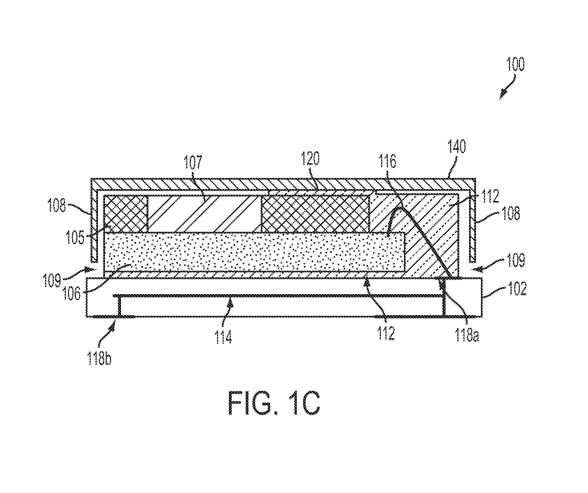

FIGS. 1A, 1B, and 1C illustrate a first embodiment of a package 100 integrated MEMS in accordance with the present invention. For example, the MEM sensors may include but not limited to gyroscope, accelerometer, magnetometer, microphone, and pressure sensor. FIG. 1A is a top view and a cross-sectional view of the package 100. FIG. 1B is a bottom view of the package 100. Referring to FIGS. 1A and 1B together the package 100 includes a substrate 102 which is coupled to a CMOS die 106 via adhesive material 112. In the described embodiments, adhesive material 112 refers to any low stress adhesive material 112, such as Room Temperature Vulcanizing (RTV) silicone elastomer. In the described embodiments, sensor chip refers to one or more CMOS with electronics and/or MEMS die containing sensor elements.

The CMOS die 106 is bonded to the MEMS die 105 through wafer bonding. In one embodiment, MEMS die 105 is bonded to CMOS die through wafer bonding techniques that use vertical fabrication processes as described in U.S. Pat. No. 7,104,129 “Vertically Integrated MEMS Structure with Electronics in a Hermetically Sealed Cavity”, which is incorporated herein by reference. MEMS die 105 may include gyroscope, accelerometer, magnetometer, microphone, and pressure sensor. In some embodiments, the MEMS die 105 includes an opening 107 and provides for example as a path for the ambient for a pressure sensor or acoustic signal for a microphone. In an embodiment, an integrated MEMS package 100 is hermetically sealed at wafer level via eutectic bonding. In an embodiment, to minimize the die size, bond wires 116 are connected to wire bond pads 118a on one side of the die. In another embodiment, the bond wires may be connected to bond pads placed on more than one side of the die. Bond pad 118a may be placed on the substrate closer to the CMOS die; bond pad 118b may be placed on the substrate away from the CMOS die and connected through connectors 114. Bond pad 118b provides a larger pitch for connecting to a PCB substrate. CMOS die 106 is then bonded to the substrate 102, using a low stress adhesive material 112, such as Room Temperature Vulcanizing (RTV) silicone elastomer which is commonly used for a pressure sensor. Substrate 102 may be a multi-layer substrate such as Land Grid Array (LGA).

Bond wire 116, wire bond pads 118a and bond pads 118b provide the electrical connections from the die 106 to the substrate 112. In an embodiment, bond wire 116 is protected with a glop-top material such as RTV silicone which has very small stress on the pressure sensor. Adhesive material 112 such as RTV silicone is selectively placed on the top surface of MEMS 120 using a standard, automatic dispenser and a lid 110 (shaped as a crown) is bonded to the MEMS 120 surface.

The process of attaching lid 100 can be an individual die or in an array. In an embodiment, the RTV silicone bond line is typically 25 μm, multiple layers of RTV silicone bond line can be applied if a thicker bond line is required to meet the device performance. The sidewalls 108 of the lid 110 have a vertical gap 109 above substrate 102. In an embodiment, the vertical gap 109 provides access to the ambient environment for pressure sensor and microphone. In a different embodiment, the vertical gap may be filled with adhesive material such that the lid is not rigidly attached to the substrate. n an embodiment, lid 110 can have an opening 104. Opening 104 can be formed close to the opening 107 of the MEMS die 105 to allow access to ambient. In an embodiment, lid 110 can be made of metal such as plated stainless steel or plastic (e.g. liquid crystal polymer). The top surface of the lid 110 can also be used for product marking 122.

In another embodiment as shown in FIG. 1C, lid 140 may have not have opening. Lid 140 may be attached by an adhesive; the adhesive is placed such that one or more channels are provided thus enabling a path for the ambient environment through vertical gap 109 to opening of MEMS die opening 107.

In another embodiment, one or more extensions may be provided from the lid to the substrate. The extensions may be made from a conductive material to provide an electrical path to ground the lid.

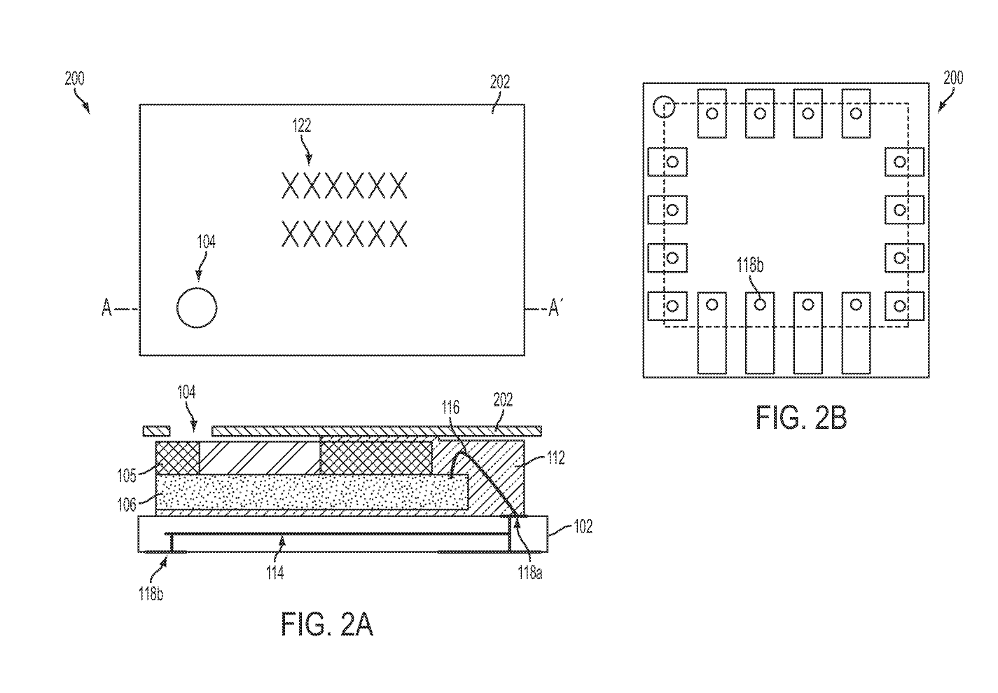

FIGS. 2A and 2B illustrate a second embodiment of a package 200 integrated MEMS sensors in accordance with the present invention. FIG. 2A is a top view and a cross-sectional view of the package 200. FIG. 2B is a bottom view of the package 200. This embodiment is the substantially similar to that of FIGS. 1A and 1B except for the lids. Lid 202 is a cover with an opening 104 but does not include the sidewall 108. In another embodiment, lid 202 may not have an opening 104.

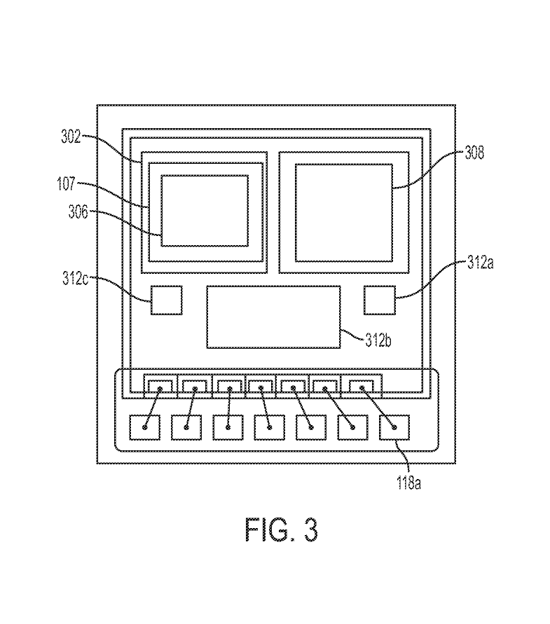

FIG. 3 illustrates a top view of either package 100 or 200 with the lid 110 or 202 removed. As is seen, opening 107 in the MEMS die 105 can interact with the ambient via opening 104 in the lid 110 or lid 202. As is also seen, the package includes a pressure sensor 302 which includes a membrane 306 in the center of the opening 107. In this embodiment, the package also includes a gyroscope 308 and three accelerometers 312a-312c.

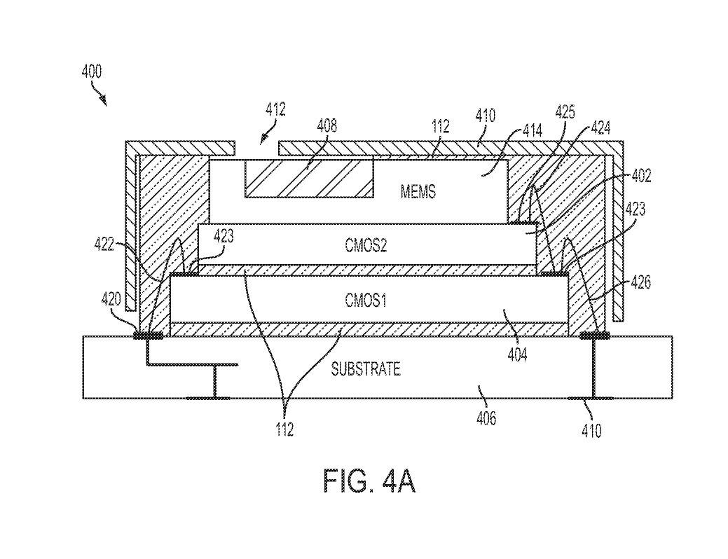

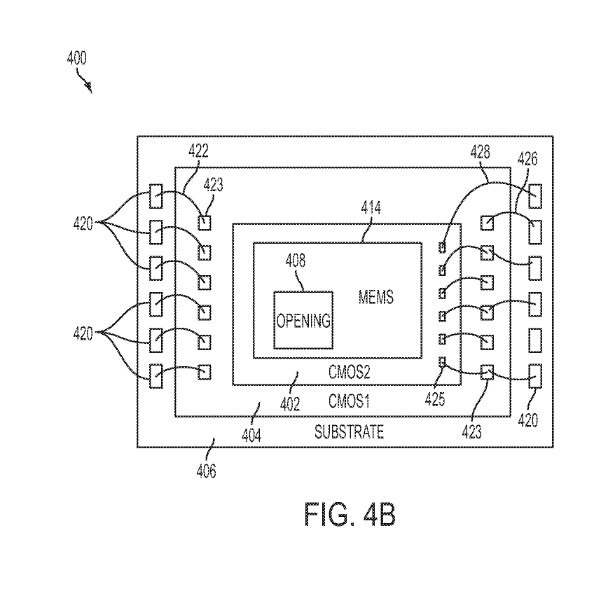

FIGS. 4A and 4B illustrate a third embodiment of an MEMS package 400 in accordance with an embodiment. FIG. 4A is a side view of the package 400 and FIG. 4B is a top view of the MEMS package 400. Referring to FIGS. 4A and 4B together, as is seen there are two stacked CMOS dies 402 and 404 between the substrate 406 and MEMS die 414. The CMOS dies 402 and 404 could be any of or any combination of electronics, sensors or solid state batteries. In this embodiment, the substrate 406 is attached to a first CMOS die 404 via adhesive material 112. The first CMOS die 404 is attached to second CMOS 402 via an adhesive material 112. The second CMOS die 402 is coupled to the MEMS die 414 by wafer bonding. MEMS die 414 has an opening 408 to expose the sensor to the ambient environment. Bond wire 422 and 426 connect from bond pads 423 to the bond pads 420 on substrate 406. The bond pads may be located on one side or more than side of the first CMOS die 404. Bond wire 424 connects bond pad 425 on the second CMOS die 402 to bond pad 423 on first CMOS die 404. In another embodiment, bond pads 425 on CMOS2 may be connected by bond wire 428 to bond pad 420 on substrate 406. Package 400 may include a lid with an opening 412 for providing an access path to ambient. Lid 410 may be attached, but not rigidly to MEMS die 414 by adhesive material 112. In some embodiments, lid 410 may include a sidewall similar to lid 110, with a vertical gap between the side wall and the substrate. In some embodiments, the vertical gap may be filled with adhesive material. In another embodiment, lid 410 may not have a side wall.

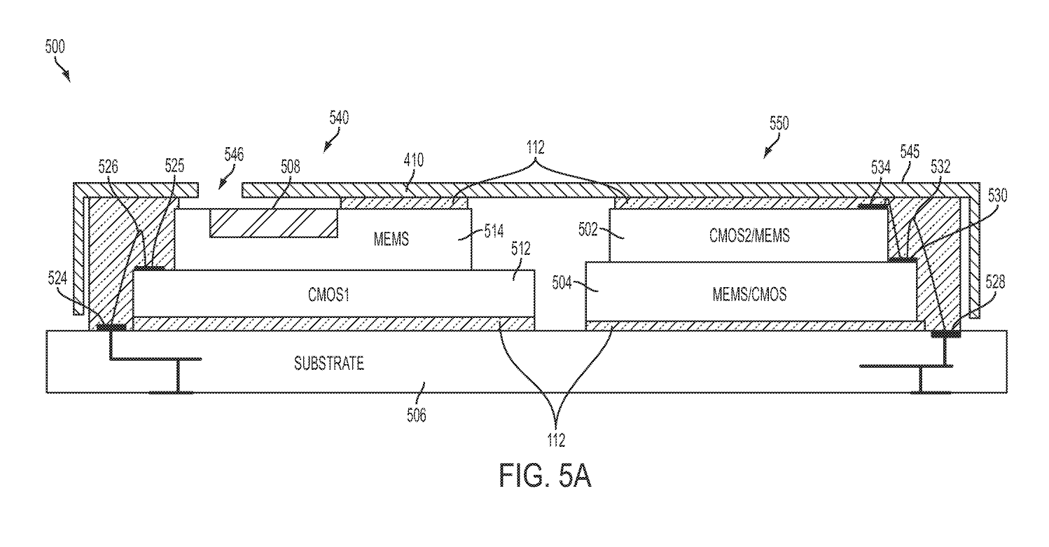

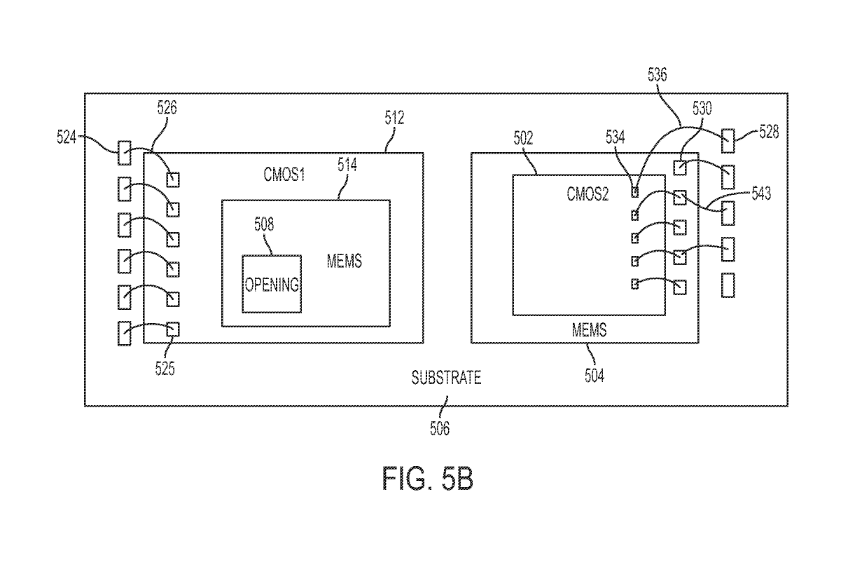

FIGS. 5A and 5B illustrate a fourth embodiment of an MEMS package 500 in accordance with an embodiment. FIG. 5A is a side view of the package 500 and FIG. 5B is a top view of the MEMS package 500. Referring to FIGS. 5A and 5B together, as is seen there are two stacks of CMOS/MEMS dies on the substrate 506.

In this embodiment, stack 550 includes a MEMS/CMOS die 504 coupled to the substrate 506 via adhesive material 112. Die 504 is coupled to the CMOS/MEMS die 502. Stack 550 can include any combination of MEMS and CMOS dies. 502 can be either a CMOS or MEMS. Similarly, 504 can be either MEMS or CMOS. In an embodiment. 502 and 504 can be coupled with adhesive material if 502 and 504 are CMOS. In another embodiment, 502 and 504 may be coupled with wafer bonding when 502 and 504 are MEMS and CMOS. In stack 540, CMOS die 512 is coupled to the substrate 506 via adhesive material 112. The CMOS die 512 is also bonded by wafer bonding to MEMS die 514. In an embodiment MEMS die 514 may include an opening 508 for a MEMS device requiring exposure to ambient. Bond wires 526 connects bond pad 525 to bond pad 524 on substrate 506. Bond wire 532 connects bond pad 530 to bond pad 528 on substrate 506. Bond wire 536 may connect bond pad 534 to bond pad 528 on substrate 506. Package 500 may include a lid 545 with or without opening 546 for providing an access path to ambient. The lid 545 may be attached to MEMS die 514 and die 502 by adhesive material 112. In some embodiments, lid 545 may include a sidewall similar to lid 110.

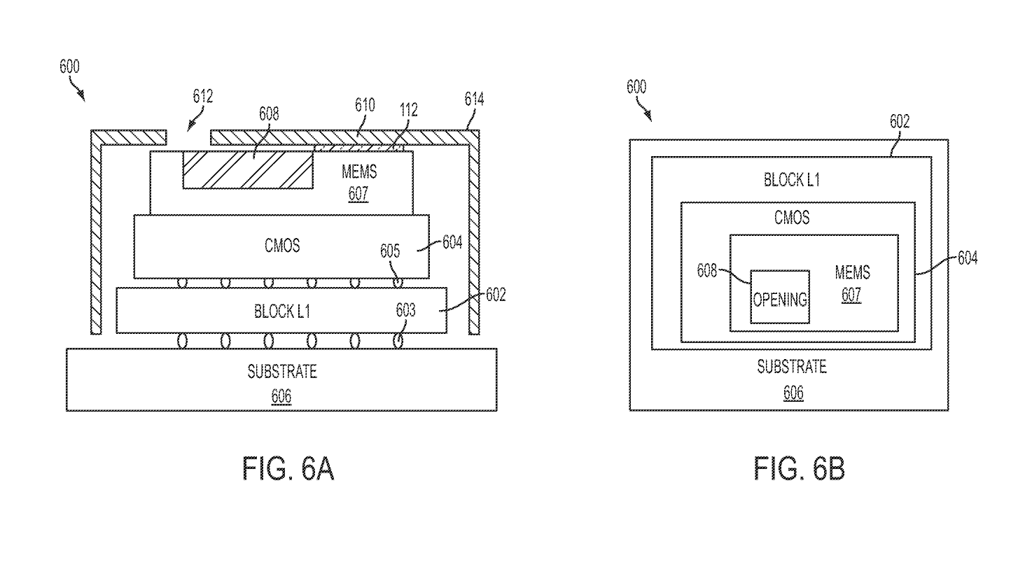

FIGS. 6A and 6B illustrate a fifth embodiment of an MEMS package 600 in accordance with an embodiment. FIG. 6A is a side view of the package 600 and FIG. 6B is a top view of the MEMS package 600. As is seen in this embodiment substrate 606 is coupled to a block 602 by solder balls 603. The block L1 602 in turn is electrically connected to the CMOS die 604 via solder balls 605. The CMOS die 604 in turn is bonded to the MEMS die 607 by wafer bonding. In an embodiment, MEMS die 607 may include an opening 608 to expose the MEMS sensor to the ambient. Lid 610 is attached to MEMS die 607 by adhesive material 112. Opening 612 provides ambient to the MEMS sensor on MEMS die 607. In an embodiment, lid 610 may have sidewalls 614 such that a vertical gap is provided between the lid and the substrate. In another embodiment lid 610 may not have sidewalls.

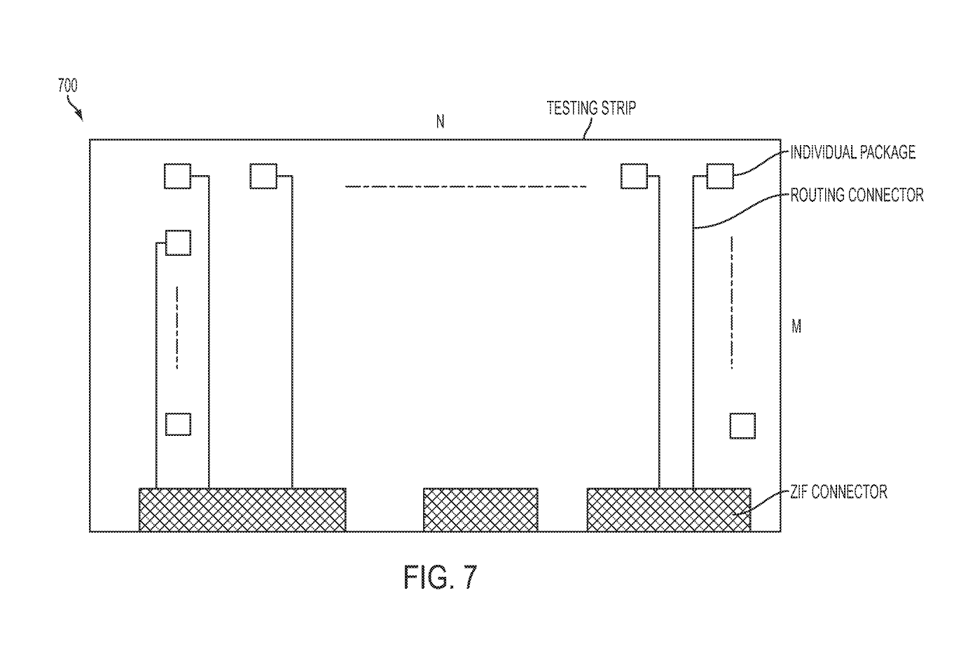

FIG. 7 describes the testing mechanism. A test strip comprising sensor chips are placed in rows (M) and columns (N) and signals are routed to Zero Insertion Force (ZIF) connectors at the edge of the boards. The ZIF connectors provide electrical interface to the sensor chips for testing without applying direct pressure on the packages. A number of sensor chips can be tested in parallel. In an embodiment, dies in a column or row are tested in parallel.

The sensor chips can be any of the integrated MEMS sensors described in the specification before attaching to the substrate. The test strip comprises of a multilayer Printed Circuit Board (PCB) with electrical signal routed from the device under test to the ZIF connectors.

Method of Testing

The sensor chips are placed on test strip in rows and columns and attached to the test substrate by an adhesive material. The substrate carrier can be a multilayer Printed Circuit Board. The adhesive material is cured before wire bonding the sensor chip to the test substrate. A lid is attached to the sensor chip using the adhesive material. In some embodiments, adhesive material is also placed so as to cover the wire bonds. The test substrate is cured before connecting to the ZIF connectors. The test substrate is placed on a testing platform for parallel testing of the sensor chips. After testing, the test strip is singulated to provide individual packages for example as in FIG. 1A

Integrated MEM sensors packages in accordance with at least some of the above-identified embodiments provide advantages in cost and product height that meet the next generation mobile consumer device component requirements. First, an edge of the lid is not bonded to the multi-layer substrate. The sidewalls of the lid have a small gap above the substrate. Second, the lid is bonded directly to the surface of the MEMS die. These features reduce the package in all three dimensions as compared to the existing open-cavity package variety.

For example, a 2.7 mm×2.4 mm×0.42 mm die can fit in a 3 mm×3 mm×0.8 mm package size. In a conventional open-cavity package, this same die would require a package size of 4 mm×4 mm×1.0 mm. A 3×3 package is only 56% the area of a 4×4 package; hence, the package cost can be reduced by approximately half. As mobile devices (smartphone and tablet) continue to reduce in thickness, the components must also scale accordingly. A package in accordance with some embodiments can reduce product height by >20% and enables new products to continue to meet the mobile, consumer market requirements.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A package comprising:
a sensor chip with a top surface and a bottom surface;
a substrate with electrical inter-connects, wherein the bottom surface is attached to the substrate; and
a lid coupled to the top surface with adhesive material.

2. The package of claim 1, wherein the lid has an opening to expose the sensor chip to ambient environment.

3. The package of claim 1, wherein the lid includes sidewalls, wherein a vertical gap is provided between the sidewalls and the substrate.

4. The package of claim 1, wherein the lid is not rigidly attached to the substrate.

5. The package of claim 1, wherein the vertical gap is filled with the adhesive material.

6. The package of claim 1, wherein the sensor chip comprises a plurality of integrated CMOS-MEMS sensors.

7. The package of claim 1, wherein adhesive material is a complaint low stress material.

8. The package of claim 7, wherein the low stress material is Room Temperature Vulcanizing (RTV) silicone elastomer.

9. The package of claim 1, further comprising a plurality of wire bond pads, the wire bond pads placed on at least one side of the sensor chip.

10. The package of claim 1, wherein the lid has an electrical connection to the substrate.

11. The package of claim 1, wherein the substrate comprises a multi-layer substrate.

12. The package of claim 1, where the substrate is formed as part of a strip comprising an array of N×M packages and package pin connections are routed to the edge of the strip to allow connection to the package pins without direct pressure on the package surface wherein the pin connections are configured in a row and column in order to allow just one row or column of packages to be tested at a time.

13. The package of claim 1, where in the sensor chip comprises at least one MEMS die and at least one CMOS die.

14. The package of claim 13 further comprising plurality of CMOS dies and plurality of MEMS dies wherein the plurality of CMOS dies and plurality of MEMS dies are placed next to the sensor chip.

15. The package of claim 1, where in the sensor chip comprises plurality of CMOS die and plurality of MEMS die wherein the plurality of CMOS die and plurality of MEMS die are stacked.

16. A package of integrated sensor comprising:
a sensor chip;
a substrate with electrical inter-connects;
a first side of the sensor chip bonded to the substrate; and
a lid with no sidewalls bonded to a second side of the sensor chip; wherein the lid has an opening to expose to ambient environment.

17. A method of packaging an integrated MEMS device, the method comprising:
attaching a sensor chip to a substrate; the sensor chip having an opening in atop surface;
connecting sensor chip to the substrate with wire bonds to make electrical connection; and
bonding a lid to the top surface of the sensor chip such that the lid covers the sensor chip with a vertical gap between the lid and the substrate.

18. The method of claim 17, where the lid has an opening to expose a portion of the sensor chip to ambient environment.

19. A method of packaging an integrated MEMS device, the method comprising:
attaching a first surface of a sensor chip to a substrate using adhesive material;
connecting the sensor chip to the substrate with wire bonds to make electrical connection;
protecting the wire bonds with low stress material on sensor chip;
bonding a lid to a second surface of the sensor chip surface such that a vertical gap between the lid and the substrate.

20. The method of claim 19, where the lid has an opening to expose a portion of the MEMS die to ambient environment.

21. The method of claim 19, where in the bonding further comprises providing a path for ambient environment to the sensor chip.

22. A package comprising:
a MEMS die with a top surface and a bottom surface; wherein the MEMS die has an opening located on the top surface;
a CMOS die with a top surface and a bottom surface;
a substrate with electrical inter-connects, wherein the MEMS die and the CMOS die are attached to the substrate in a side by side fashion, wherein the bottom surfaces of the MEMS die and the CMOS die are attached to the substrate; wherein a path from the ambient environment to the opening of the MEMS die is provided.
